(19) United States
(12) Patent Application Publication
(10) Pub. No.: US 2025/0172627 A1
(43) Pub. Date: May 29, 2025

(54) BATTERY DETERIORATION ESTIMATION APPARATUS

(71) Applicant: HONDA MOTOR CO., LTD., Tokyo (JP)

(72) Inventors: Pu QIAN, Saitama (JP); Tomohiro KINOSHITA, Saitama (JP); Takaharu WATANABE, Saitama (JP); Takafumi NAGAI, Saitama (JP); Wataru SHIMIZU, Saitama (JP)

(21) Appl. No.: 18/959,636

(22) Filed: Nov. 26, 2024

(30) Foreign Application Priority Data
Nov. 27, 2023 (JP) 2023-199896

(51) Int. Cl. G01R 31/392; G01R 31/389

(52) U.S. Cl. CPC G01R 31/392; G01R 31/389

(57) ABSTRACT

A battery deterioration estimation apparatus is equipped with a current measurement unit, a voltage measurement unit, a calculation unit, and an estimation unit. The current measurement unit measures a discharge current of the secondary battery at a prescribed timing that is directly after the start of discharge by the secondary battery. The voltage measurement unit measures a voltage drop that is the difference between the voltage of the secondary battery before the start of discharge and the voltage of the secondary battery at the prescribed timing described above. The calculation unit calculates the internal impedance of the secondary battery at the above-described prescribed timing from the measured discharge current and the measured voltage drop. The estimation unit estimates the degree of deterioration of the secondary battery from the calculated internal impedance.

This application is based on and claims the benefit of priority from Japanese Patent Application No. 2023-199896, filed on 27 Nov. 2023, the content of which is incorporated herein by reference.

### BACKGROUND OF THE INVENTION

### Field of the Invention

The present invention pertains to a battery deterioration estimation apparatus that estimate a degree of deterioration of a secondary battery.

### Related Art

In recent years, the spread of electric vehicles such as EVs and HEVs has proceeded from a perspective of, inter alia, reducing emission of carbon dioxide to thereby reduce adverse effects on the global environment. Secondary batteries that are mounted to electric vehicles or the like include those that are configured as follows. A secondary battery that includes a positive electrode, a negative electrode having a metallic lithium layer, and an electrolyte that is provided between the positive electrode and the negative electrode.

Patent Document 1: Japanese Unexamined Patent Application, Publication No. 2023-87844

### SUMMARY OF THE INVENTION

In such a secondary battery, in conjunction with repeating charging and discharging, an SEI film is formed and grows in the metallic lithium layer in the negative electrode. Note that the “SEI” referred to here is an abbreviation of “Solid Electrolyte Interphase”.

The inventors considered estimating a degree of deterioration of the secondary battery, based on a degree of growth of the SEI film. This is because growth of an SEI film means a decrease in the activity of the metallic lithium in the negative electrode. Accordingly, if the degree of growth of the SEI film is understood, it is possible to estimate a degree of decrease in the activity of the metallic lithium, and thereby estimate the degree of deterioration of the secondary battery.

The electrical resistance of the SEI film increases in conjunction with growth of the SEI film. In a state where the SEI film has grown to a certain extent or more, the electrical resistance of the SEI film accounts for a large proportion of the internal impedance of the entirety of the secondary battery. As a result, it is possible to estimate the degree of growth of the SEI film, based on the internal impedance of the secondary battery. It is possible to estimate a degree of deterioration of the secondary battery based on this degree of growth.

However, the inventors also paid attention to the presence of problems that are described below. When the secondary battery is discharging, dissolution and precipitation of metallic lithium within the metallic lithium layer becomes steady. In other words, it becomes steady that metallic lithium in a portion that is more on the negative electrode side than the SEI film within the metallic lithium layer once dissolves, passes through the SEI film, and then is incorporated into a positive electrode active material. In this process, diffusion resistance accounts for a larger proportion of the internal impedance of the secondary battery. Accordingly, it is not possible to accurately measure the electrical resistance of the SEI film. Therefore, it is not possible to accurately estimate the degree of growth of the SEI film. As a result, it is also not possible to accurately estimate the degree of deterioration of the secondary battery, based on the degree of growth.

The present invention is made in light of the circumstances described above, and an object of the present invention is to enable accurate estimation of a degree of deterioration of a secondary battery that has a metallic lithium layer in a negative electrode.

The inventors accomplished the present invention by finding that it is possible to accurately estimate a degree of growth of an SEI film, based on the internal impedance of a secondary battery directly after discharge starts. The present invention is a battery deterioration estimation apparatus according to (1) through (6) below, as well as a battery deterioration estimation method according to (7) below.

(1) A battery deterioration estimation apparatus for estimating a degree of deterioration of a secondary battery that includes a positive electrode, a negative electrode, and an electrolyte provided between the positive electrode and the negative electrode, the negative electrode having a metallic lithium layer, the battery deterioration estimation apparatus including:
a current measurer configured to measure a discharge current of the secondary battery at a prescribed timing directly after a start of discharging by the secondary battery;
a voltage measurer configured to measure a voltage drop that is a difference between a voltage of the secondary battery before the start of discharging and a voltage of the secondary battery at the prescribed timing;
a calculator configured to calculate an internal impedance of the secondary battery at the prescribed timing from the measured discharge current and the measured voltage drop; and
an estimator configured to estimate the degree of deterioration of the secondary battery from the calculated internal impedance.

By virtue of this configuration, the current measurer, the voltage measurer, and the calculator are used to obtain the internal impedance of the secondary battery directly after the start of discharge. Directly after the start of discharge, dissolution and precipitation of metallic lithium has not yet become steady within the metallic lithium layer. As a result, a decrease of a battery voltage due to diffusion resistance has not yet become full-fledged in the entirety of the secondary battery. The estimator can accurately estimate the degree of growth of an SEI film from the internal impedance of the secondary battery in this state. As a result, it is possible to accurately estimate the degree of deterioration of the secondary battery. By virtue of the present configuration, it is possible to accurately estimate a degree of deterioration of a secondary battery that has a metallic lithium layer in a negative electrode.

(2) The battery deterioration estimation apparatus according to (1) above, the prescribed timing being a timing at which a prescribed amount of time that is greater than or equal to 0.001 seconds and less than or equal to 1.0 seconds has elapsed from the start of discharging by the secondary battery.

Although it is possible to more effectively exclude effects such as diffusion resistance if the amount of discharge time is short, when the amount of discharge time is too short, there is a greater chance of being affected by the inductance of a harness or the like, and accurate measurement is not possible. On this point, by virtue of this configuration, the prescribed timing, which corresponds to a timing for measuring the internal impedance of the secondary battery, is before 1.0 seconds from the start of discharge has elapsed. Therefore, the amount of discharge time is sufficiently short and it is possible to more effectively exclude the effect of diffusion resistance or the like. In addition, this timing is after 0.001 seconds or more has elapsed from the start of discharging by the secondary battery. Therefore, the amount of discharge time will not be too short and there is a lower chance of being affected by the inductance of a harness or the like. Consequently, it is possible to accurately estimate the degree of growth of the SEI film.

(3) The battery deterioration estimation apparatus according to (1) or (2) above, further including:
a second current measurer configured to measure a second discharge current that is a discharge current of the secondary battery at a second prescribed timing that is after the prescribed timing;
a second voltage measurer configured to measure a second voltage drop that is a difference between the voltage of the secondary battery before the start of discharging and a voltage of the secondary battery at the second prescribed timing;
a second calculator configured to calculate an internal impedance of the secondary battery at the second prescribed timing from the measured second discharge current and the measured second voltage drop,
the estimator comprehensively estimating the degree of deterioration of the secondary battery from the calculated internal impedance at the prescribed timing, and the calculated internal impedance at the second prescribed timing.

By virtue of the present configuration, the second current measurer, the second voltage measurer, and the second calculator are used to obtain the internal impedance of the secondary battery at the second prescribed timing that is after the prescribed timing. It was confirmed that the internal impedance at this second prescribed timing suddenly increases when the capacity of the secondary battery suddenly decreases. Accordingly, it is possible to also use the internal impedance at this second prescribed timing to more accurately estimate the degree of deterioration of the secondary battery.

(4) The battery deterioration estimation apparatus according to (3) above, the second prescribed timing being a timing at which a prescribed amount of time that is greater than or equal to 3.0 seconds and less than or equal to 30 seconds has elapsed from the start of discharging by the secondary battery.

By virtue of this configuration, the second prescribed timing that serves as a timing for measuring the internal impedance of the secondary battery is after three or more seconds from the start of discharge by the secondary battery have elapsed. Therefore, it is possible to sufficiently ensure an amount of time for the internal impedance of the secondary battery to become steady. In addition, the second prescribed timing is before 30 seconds from the start of discharge has elapsed. Therefore, it is possible to avoid wastefully taking a large amount of time to obtain the internal impedance.

(5) The battery deterioration estimation apparatus according to (1) or (2) described above, the secondary battery and the battery deterioration estimation apparatus being mounted to a vehicle.

By virtue of this configuration, it is possible to estimate a degree of deterioration of a secondary battery, within a vehicle.

(6) The battery deterioration estimation apparatus according to (5) above, further including a reporter configured to, on a condition that the estimator has determined that the secondary battery has deteriorated up to or greater than a prescribed reference, report to a driver of the vehicle that the secondary battery has deteriorated.

By virtue of this configuration, when the secondary battery has deteriorated, the driver of the vehicle can quickly recognize this.

(7) A battery deterioration estimation method for estimating a degree of deterioration of a secondary battery that includes a positive electrode, a negative electrode, and an electrolyte provided between the positive electrode and the negative electrode, the negative electrode having a metallic lithium layer, the battery deterioration estimation method including:
measuring a discharge current of the secondary battery at a prescribed timing directly after a start of discharging by secondary battery;
measuring a voltage drop that is a difference between a voltage of the secondary battery before the start of discharging and a voltage of the secondary battery at the prescribed timing;
calculating an internal impedance of the secondary battery at the prescribed timing from the measured discharge current and the measured voltage drop; and
estimating the degree of deterioration of the secondary battery from the calculated internal impedance.

By virtue of this method, an effect that is similar to that of the case of the apparatus according to (1) described above is achieved.

By virtue of the apparatus according to (1) above and the method according to (7) above, it is possible to accurately estimate a degree of growth of an SEI film, for a secondary battery that has a metallic lithium layer in a negative electrode. Furthermore, by virtue of the configurations according to (2) through (6) above, which cite (1) above, respective additional effects are achieved.

### BRIEF DESCRIPTION OF THE DRAWINGS

FIG. 1 is a block diagram that illustrates a battery deterioration estimation apparatus according to a first embodiment;

FIG. 2 is a circuit diagram that illustrates a circuit that is inside a vehicle;

FIG. 3 is a circuit diagram that illustrates a situation at a time of discharging;

FIG. 4 is a circuit diagram that illustrates a situation at a time of charging;

FIG. 5 is a circuit diagram that illustrates a state in which an SEI film has been formed;

FIG. 6 is a circuit diagram that illustrates the internal impedance of a secondary battery;

FIG. 7 is a graph that illustrates a relationship between the thickness of an SEI film and an impedance after 0.1 seconds;

FIG. 8 is a graph that illustrates a relationship between an amount of discharge time and an inter-terminal voltage for a secondary battery;

FIG. 9 is a graph that illustrates a relationship between a number of cycles for charging and discharging and an impedance after 10 seconds, and a relationship between the same number of cycles and the capacity of a secondary battery;

FIG. 10 is a graph that illustrates a relationship between a number of cycles for charging and discharging, and an impedance after 0.1 seconds; and

FIG. 11 is a block diagram that illustrates a battery deterioration estimation apparatus according to a second embodiment.

### DETAILED DESCRIPTION OF THE INVENTION

With reference to the drawings, description is given below regarding embodiments of the present invention. However, the present invention is not limited whatsoever to the following embodiments, and can be worked after being changed, as appropriate, within a range that does not deviate from the spirit of the present invention.

### First Embodiment

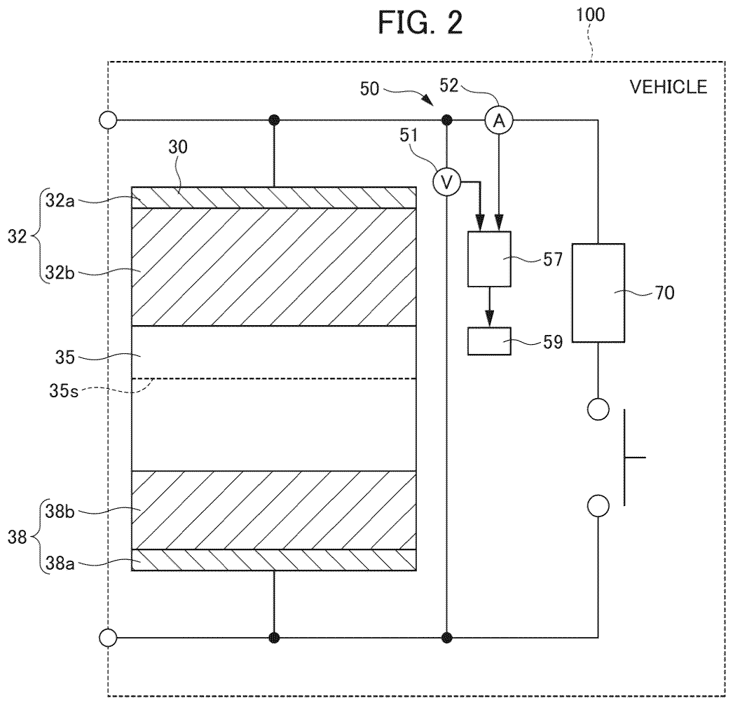

A battery deterioration estimation apparatus 50 according to the present embodiment is mounted to a vehicle 100, as illustrated in FIG. 2. An electrical device 70 and a secondary battery 30 are also mounted to the vehicle 100. The electrical device 70 includes a power control unit (PCU), or the like. The secondary battery 30 supplies electric power to the electrical device 70. The battery deterioration estimation apparatus 50 estimates a degree of deterioration of the secondary battery 30.

The secondary battery 30 is a semi-solid battery, and is provided with a positive electrode 38, a negative electrode 32, and an electrolyte 35. The positive electrode 38 is provided with a positive electrode current collector 38a and a positive electrode active material layer 38b. The positive electrode current collector 38a is formed from a current collector foil that is made of aluminum or the like, for example. The positive electrode active material layer 38b is a layer of, inter alia, lithium cobalt oxide, for example. The negative electrode 32 is provided with a negative electrode current collector 32a and a negative electrode active material layer 32b. The negative electrode current collector 32a is formed from a current collector foil that is made of copper or the like, for example. The negative electrode active material layer 32b is a metallic lithium layer. The electrolyte 35 is a semi-solid electrolyte that includes lithium ions Li+. A separator 35s is used to partition the electrolyte 35 into a positive electrode 38 side and a negative electrode 32 side.

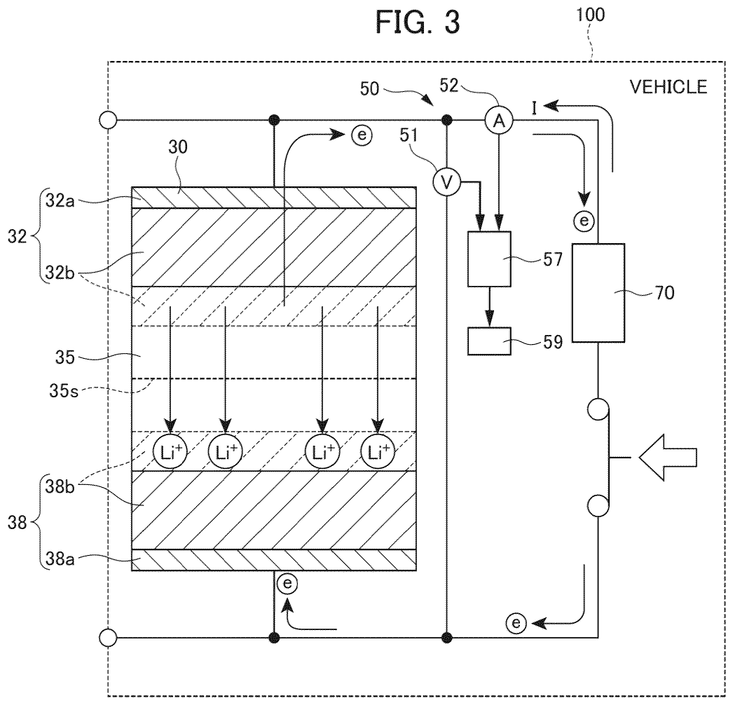

As illustrated in FIG. 3, at a time of discharging where the secondary battery 30 supplies electric power to the electrical device 70, lithium ions Li⁺ from the negative electrode active material layer 32b flow to the positive electrode 38 side on a path that passes through the separator 35s. Together with this, electrons e from the negative electrode 32 flow to the positive electrode 38 side on a path that passes through a circuit in the electrical device 70. As a result, within the vehicle 100, a current I flows from the positive electrode 38 side toward the negative electrode 32 side, whereby the secondary battery 30 is discharged. In conjunction with this discharging, the metallic lithium dissolves within the negative electrode active material layer 32b.

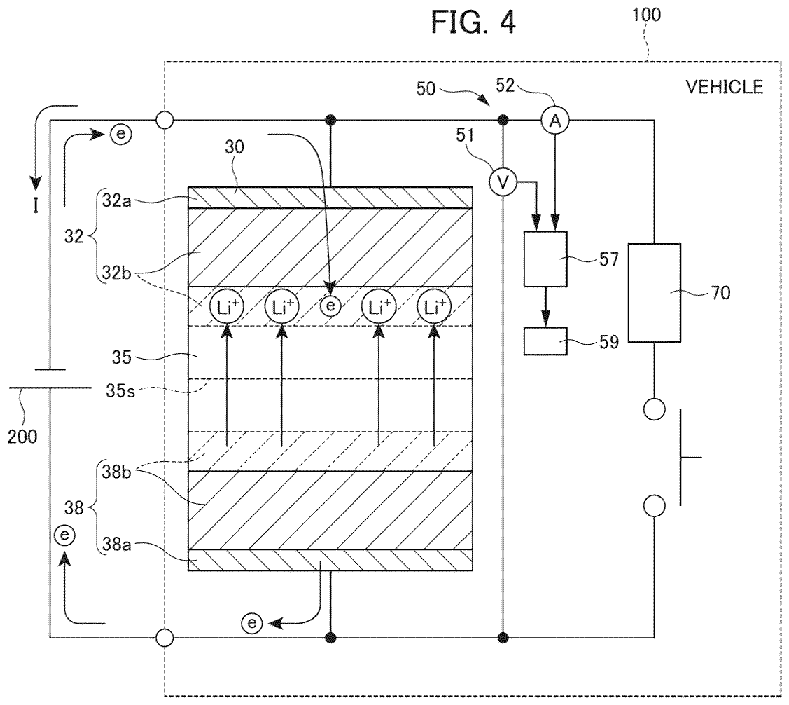

As illustrated in FIG. 4, at a time of charging where the secondary battery 30 is charged by a charging power source 200 that is outside of the vehicle 100, lithium ions Li⁺ from the positive electrode active material layer 38b flow to the negative electrode 32 side on a path that passes through the separator 35s. Together with this, electrons e from the positive electrode 38 flow to the negative electrode 32 side on a path that passes through the charging power source 200. As a result, a current I flows from the negative electrode 32 side toward the positive electrode 38 side, whereby the secondary battery 30 is charged. In conjunction with this charging, metallic lithium precipitates in the negative electrode active material layer 32b.

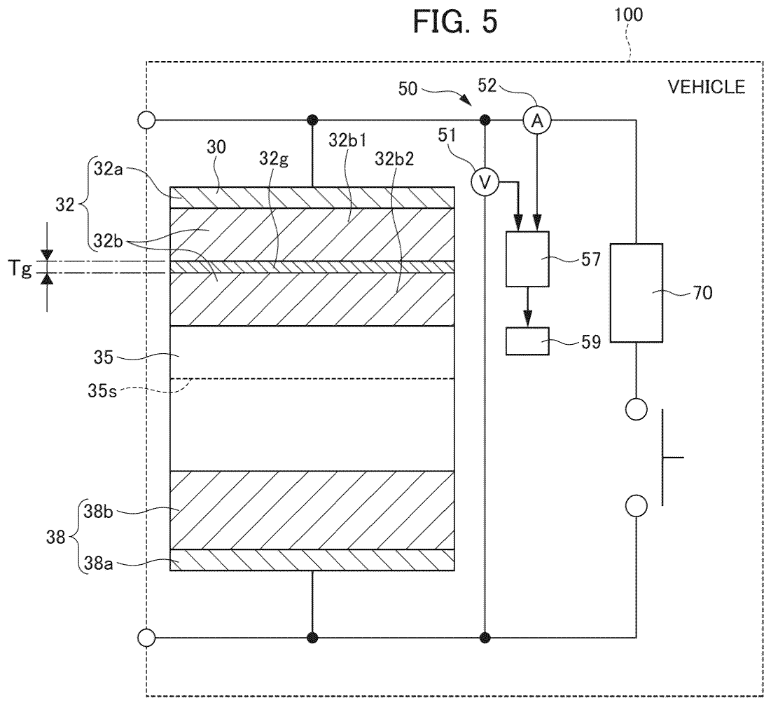

As a result of such charging and discharging being repeated, an SEI film 32g that is illustrated in FIG. 5 is formed and grows in the negative electrode active material layer 32b. In other words, a thickness Tg of the SEI film 32g increases.

Below, a portion that is within the negative electrode active material layer 32b and is more on the negative electrode current collector 32a side than the SEI film 32g is referred to as a “surplus layer 32b1”, and a portion that is within the negative electrode active material layer 32b and is more on the positive electrode 38 side than the SEI film 32g is referred to as a “precipitation layer 32b2”.

Next, description is given regarding principles of the battery deterioration estimation apparatus 50. The battery deterioration estimation apparatus 50 determines a degree of deterioration of the secondary battery 30, based on a degree of growth of the SEI film 32g. This is because growth of the SEI film 32g means a decrease in the activity of the metallic lithium in the negative electrode active material layer 32b. Accordingly, if the state of growth of the SEI film 32g is understood, it is possible to estimate a degree of decrease of the activity of the metallic lithium, and thereby estimate the degree of deterioration of the secondary battery 30.

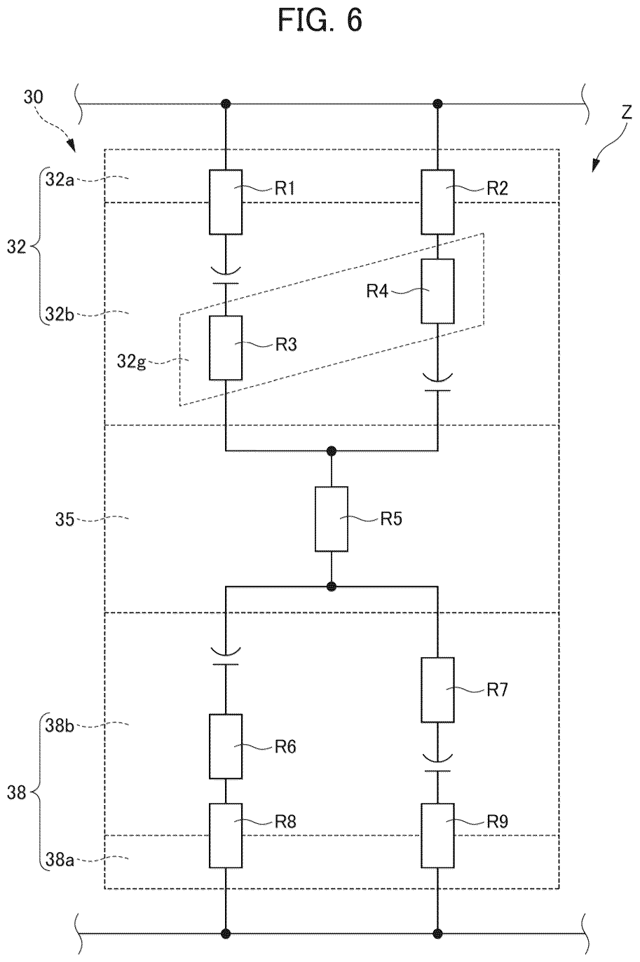

The electrical resistance of the SEI film 32g is referred to below as “SEI film resistances R3, R4”, as illustrated in FIG. 6. The SEI film resistances R3, R4 increase in conjunction with growth of the SEI film 32g. In a state where the SEI film 32g has grown by a certain extent or more, the electrical resistance of the SEI film 32g accounts for a large proportion of an internal impedance Z for the entirety of the secondary battery 30.

Specifically, as illustrated in FIG. 6, the internal impedance Z of the secondary battery 30 includes, as well as the SEI film resistances R3, R4, negative electrode interlayer resistances R1, R2, a separator resistance R5, positive electrode internal resistances R6, R7, positive electrode interlayer resistances R8, R9, or the like, for example.

The negative electrode interlayer resistances R1, R2 are conduction resistances for electrons e between the negative electrode current collector 32a and the negative electrode active material layer 32b. The SEI film resistances R3, R4 are conduction resistances for electrons e in the SEI film 32g. The separator resistance R5 is conduction resistance for lithium ions Li⁺ in the separator 35s. The positive electrode internal resistances R6, R7 are conduction resistances for lithium ions Li⁺ within the positive electrode active material layer 38b. The positive electrode interlayer resistances R8, R9 are conduction resistances for electrons e between the positive electrode current collector 38a and the positive electrode active material layer 38b. When the SEI film 32g grows, the proportion of the SEI film resistances R3, R4 in the internal impedance Z which is for the entirety of the secondary battery 30 and includes each of these elements, increases.

For the above reason, the battery deterioration estimation apparatus 50 predicts a state of deterioration of the secondary battery 30 based on the internal impedance Z of the secondary battery 30.

However, there are also problems as described below. When the secondary battery 30 is discharging, dissolution and precipitation of metallic lithium within the negative electrode active material layer 32b becomes steady. In other words, within the negative electrode active material layer 32b illustrated in FIG. 5, it becomes steady that the metallic lithium in the surplus layer 32b1 once dissolves, passes through the SEI film 32g, and is incorporated into the positive electrode active material layer 38b. In this process, diffusion resistance accounts for a larger proportion of the internal impedance Z of the secondary battery 30. Accordingly, it is not possible to accurately measure the SEI film resistances R3, R4 illustrated in FIG. 6. Therefore, it is not possible to accurately estimate the degree of growth of the SEI film 32g, which is illustrated in FIG. 5. As a result, it is not possible to accurately estimate the degree of deterioration of the secondary battery 30.

For the above reason, the battery deterioration estimation apparatus 50 illustrated in FIG. 5 estimates the degree of deterioration of the secondary battery 30, based on the internal impedance Z of the secondary battery 30 at a prescribed timing that is directly after the start of discharging by the secondary battery 30. This is because, directly after the start of discharging by the secondary battery 30, the dissolution and precipitation of metallic lithium as described above has not yet become steady. Specifically, this “prescribed timing” is a timing at which 0.1 seconds has elapsed from the start of discharging by the secondary battery 30. This timing is referred to below as a “timing after 0.1 seconds”.

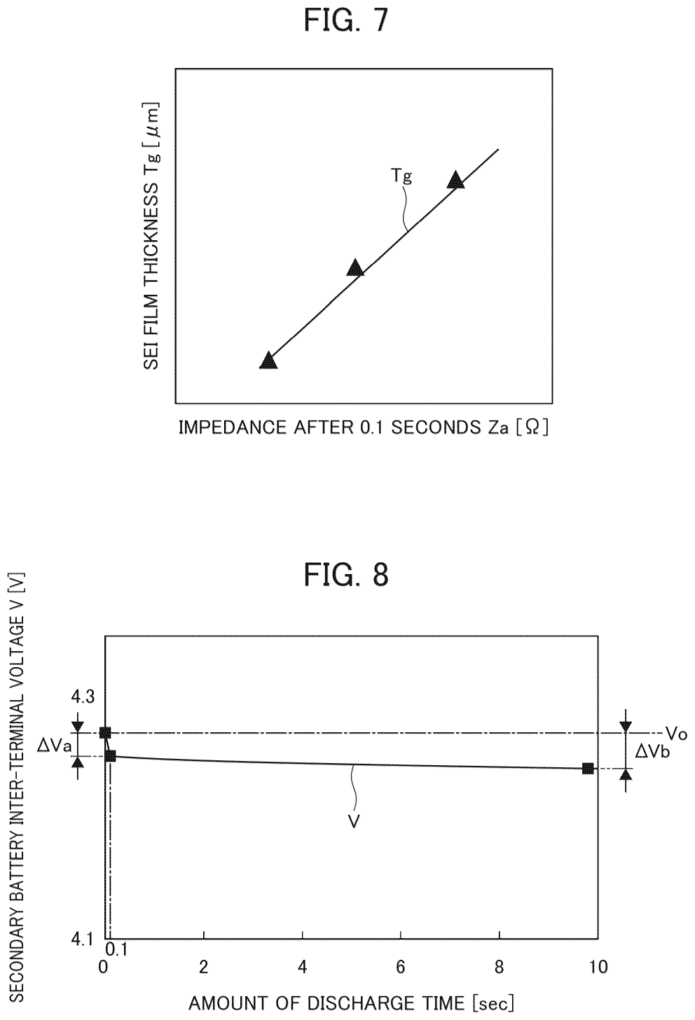

In addition, a discharge current of the secondary battery 30 at the timing after 0.1 seconds is referred to below as a “current after 0.1 seconds Ia”. In addition, as illustrated in FIG. 8, the difference between an inter-terminal voltage Vo for the secondary battery 30 before the start of discharging and an inter-terminal voltage V for the secondary battery 30 at the timing after 0.1 seconds is referred to as a “voltage drop after 0.1 seconds ΔVa”. In addition, as illustrated in FIG. 7, the internal impedance Z of the secondary battery 30 at the timing after 0.1 seconds is referred to as an “impedance after 0.1 seconds Za”. As illustrated in FIG. 7, the impedance after 0.1 seconds Za increases in conjunction with an increase of the thickness Tg of the SEI film.

Next, description is given regarding a configuration of the battery deterioration estimation apparatus 50 illustrated in FIG. 3. The battery deterioration estimation apparatus 50 is provided with a voltage detector 51, a current detector 52, a computing apparatus 57, and a reporting apparatus 59.

The voltage detector 51 detects the inter-terminal voltage V of the secondary battery 30. The current detector 52 detects a current I that flows from the positive electrode 38 side of the secondary battery 30 to the negative electrode 32 side thereof. As a result, the discharge current of the secondary battery 30 is detected when the secondary battery 30 is discharging. Based on the discharge current and the inter-terminal voltage V, the computing apparatus 57 estimates the degree of growth of the SEI film 32g in the metallic lithium layer to thereby suppose the degree of deterioration of the secondary battery 30.

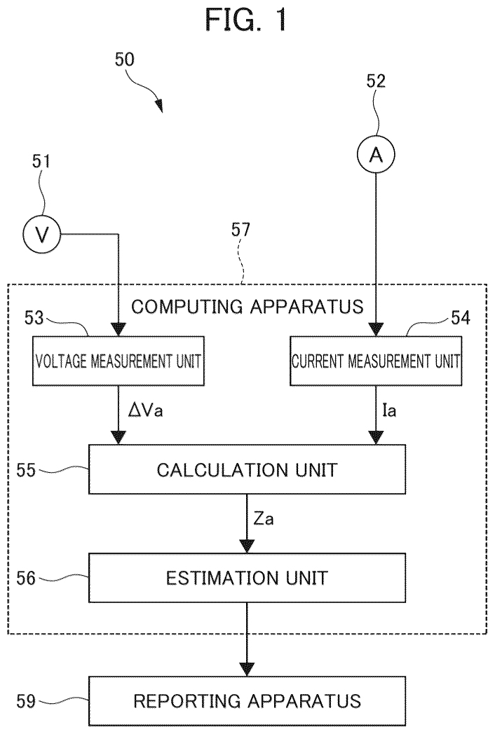

Specifically, as illustrated in FIG. 1, the computing apparatus 57 is provided with a voltage measurement unit 53, a current measurement unit 54, a calculation unit 55, and an estimation unit 56.

The current measurement unit 54 measures the current after 0.1 seconds Ia based on information from the current detector 52. The voltage measurement unit 53 measures the voltage drop after 0.1 seconds ΔVa based on information from the voltage detector 51.

The calculation unit 55 calculates the impedance after 0.1 seconds Za from the voltage drop after 0.1 seconds ΔVa measured by the voltage measurement unit 53 and the current after 0.1 seconds Ia measured by the current measurement unit 54. In other words, a value (ΔVa/Ia) resulting from dividing the voltage drop after 0.1 seconds ΔVa by the current after 0.1 seconds Ia is calculated as the impedance after 0.1 seconds Za.

The estimation unit 56 estimates the degree of growth of the SEI film 32g within the negative electrode active material layer 32b illustrated in FIG. 5, from the impedance after 0.1 seconds Za calculated by the calculation unit 55. Specifically, the estimation unit 56, for example, has a table that indicates a relationship between information that is based on the impedance after 0.1 seconds Za and a degree of growth of the SEI film 32g. The degree of growth of the SEI film 32g is estimated based on this table.

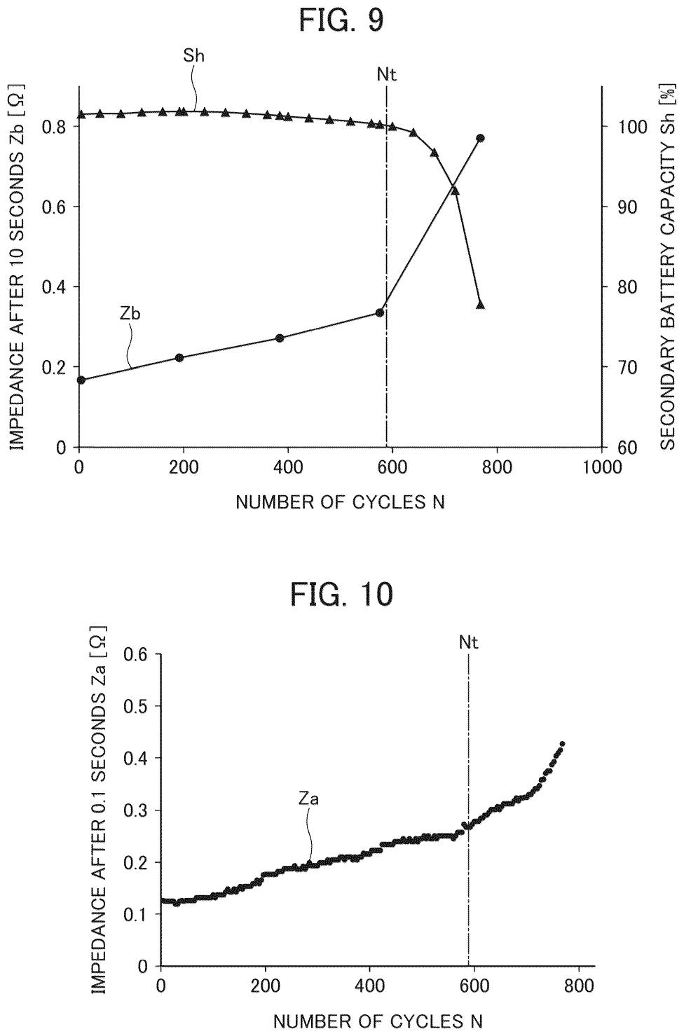

More specifically, as illustrated in FIG. 10, the inventors confirmed by experiment that the impedance after 0.1 seconds Za gradually increases in conjunction with an increase in the number of cycles N of charging and discharging. Furthermore, it was confirmed that the rate of increase of the impedance after 0.1 seconds Za—in other words, the inclination of “Za” illustrated in FIG. 10—suddenly increases from a prescribed number of cycles Nt. A capacity Sh of the secondary battery 30 suddenly decreases from the prescribed number of cycles Nt, as illustrated in FIG. 9.

As a result, the estimation unit 56 determines that the degree of growth of the SEI film 32g has reached a prescribed reference at a location where the inclination of “Za” suddenly increases. Specifically, for example, the information based on the impedance after 0.1 seconds Za in the table described above includes one or more from among “Za”, the inclination of “Za”, and the rate of increase of the inclination of “Za”. The estimation unit 56 estimates the degree of growth of the SEI film 32g from the table described above and the information based on the impedance after 0.1 seconds Za. Whether or not the SEI film 32g has grown up to or greater than the prescribed reference is determined from this degree of growth. The estimation unit 56, on the condition of having determined that there is growth up to or greater than the prescribed reference, determines that the secondary battery 30 has deteriorated up to or greater than a prescribed reference, and transmits a report signal to the reporting apparatus 59.

Upon receiving the report signal, the reporting apparatus 59 illustrated in FIG. 1 reports to a driver of the vehicle 100 illustrated in FIG. 2 that the secondary battery 30 has deteriorated. For example, this reporting may be a visual report such as by a lamp or a display by a display device, may be an audio report such as a warning sound or an announcement, or may be a visual and audio report.

The configuration and effects of the present embodiment are summarized below.

By virtue of the present embodiment, the impedance after 0.1 seconds Za is obtained by collaboration between the voltage detector 51, the current detector 52, the voltage measurement unit 53, the current measurement unit 54, and the calculation unit 55, as illustrated in FIG. 1. At the timing after 0.1 seconds, which is a timing for obtaining the impedance after 0.1 seconds Za, dissolution and precipitation of metallic lithium as described above has not yet become steady within the negative electrode active material layer 32b which is illustrated in FIG. 5. As a result, a decrease of the inter-terminal voltage V due to diffusion resistance has not yet become full-fledged in the entirety of the secondary battery 30. The estimation unit 56 can accurately estimate the degree of growth of the SEI film 32g illustrated in FIG. 5 from the internal impedance Z of the secondary battery 30 in this state. As a result, it is possible to accurately estimate the degree of deterioration of the secondary battery 30.

Moreover, the secondary battery 30 and the battery deterioration estimation apparatus 50 are mounted to the vehicle 100. Accordingly, it is possible to estimate the degree of deterioration of the secondary battery 30 within the vehicle 100.

Moreover, the reporting apparatus 59, on the condition that the estimation unit 56 has determined that the secondary battery 30 has deteriorated up to or greater than the prescribed reference, reports to the driver of the vehicle 100 that the secondary battery 30 has deteriorated. Accordingly, when the secondary battery 30 has deteriorated, the driver of the vehicle can quickly recognize this.

Note that usage of the battery deterioration estimation apparatus 50 described above corresponds to performing a battery deterioration estimation method.

### Second Embodiment

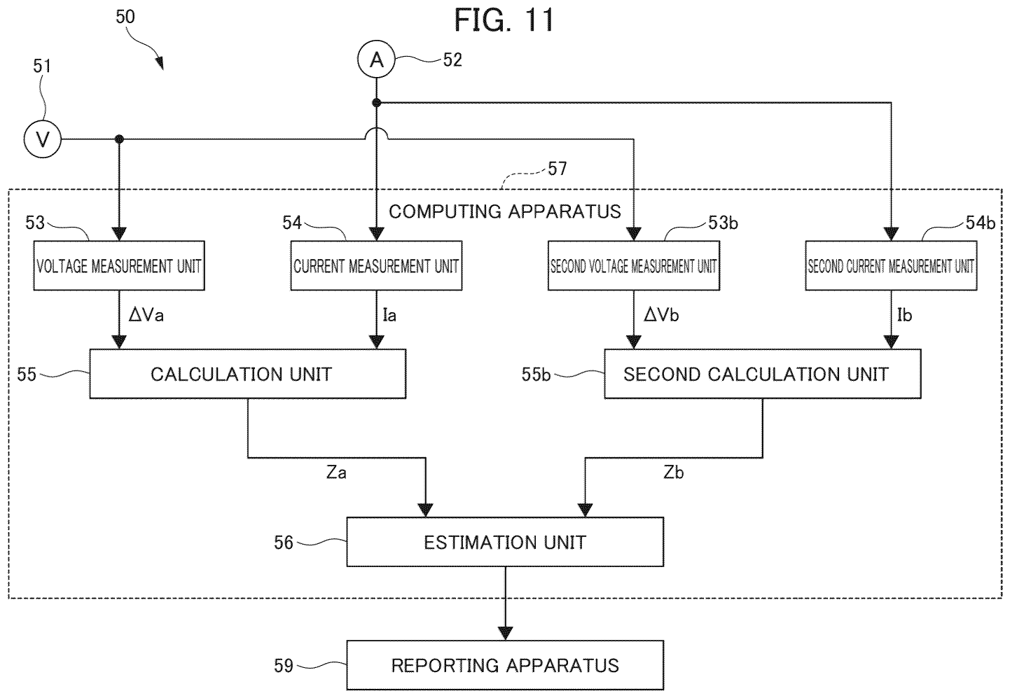

Next, with reference to FIG. 11, description is given regarding a second embodiment. Regarding the present embodiment, description is mainly given for different features based on the first embodiment. Description is omitted, as appropriate, for features that are the same as or similar to those of the first embodiment.

The battery deterioration estimation apparatus 50 according to the present embodiment estimates the degree of deterioration of the secondary battery 30, further based on the internal impedance Z of the secondary battery 30 at a second prescribed timing that is after the timing after 0.1 seconds. Specifically, this “second prescribed timing” is a timing at which 10 seconds have elapsed from the start of discharging by the secondary battery 30. This timing is referred to below as a “timing after 10 seconds”.

In addition, a discharge current of the secondary battery 30 at the timing after 10 seconds is referred to below as a “current after 10 seconds Ib”. In addition, as illustrated in FIG. 8, the difference between an inter-terminal voltage Vo for the secondary battery 30 before the start of discharging and an inter-terminal voltage V for the secondary battery 30 at the timing after 10 seconds is referred to as a “voltage drop after 10 seconds ΔVb”. In addition, the internal impedance Z of the secondary battery 30 at the timing after 10 seconds is referred to as an “impedance after 10 seconds Zb”. Note that the “current after 10 seconds Ib” may be interpreted as a “second discharge current”. In addition, the “voltage drop after 10 seconds ΔVb” may be interpreted as a “second voltage drop”.

As illustrated in FIG. 11, from the state in the first embodiment, the computing apparatus 57 is also provided with a second voltage measurement unit 53b, a second current measurement unit 54b, and a second calculation unit 55b. The second voltage measurement unit 53b measures the voltage drop after 10 seconds ΔVb based on information from the voltage detector 51. The second current measurement unit 54b measures the current after 10 seconds Ib based on information from the current detector 52.

The second calculation unit 55b calculates the impedance after 10 seconds Zb from the voltage drop after 10 seconds ΔVb measured by the second voltage measurement unit 53b and the current after 10 seconds Ib measured by the second current measurement unit 54b. In other words, a value (ΔVb/Ib) resulting from dividing the voltage drop after 10 seconds ΔVb by the current after 10 seconds Ib is calculated as the impedance after 10 seconds Zb.

The estimation unit 56 comprehensively estimates the degree of deterioration of the secondary battery 30, from the impedance after 0.1 seconds Za calculated by the calculation unit 55 and the impedance after 10 seconds Zb calculated by the second calculation unit 55b. Specifically, for example, the estimation unit 56 has a table that indicates a relationship between multiple sources of information, which includes information based on the impedance after 0.1 seconds Za and information based on the impedance after 10 seconds Zb and a degree of growth of the SEI film 32g and. The degree of growth of the SEI film 32g is estimated based on this table.

More specifically, as illustrated in FIG. 9, the inventors confirmed by experiment that the impedance after 10 seconds Zb increases in conjunction with an increase in the number of cycles N of charging and discharging. Furthermore, it was confirmed that the rate of increase of the impedance after 10 seconds Zb—in other words, the inclination of “Zb” illustrated in FIG. 9—suddenly increases from a prescribed number of cycles Nt. Note that a reason for this is considered to be that the surplus layer 32b1, which is illustrated in FIG. 5, is depleted at the prescribed number of cycles Nt. As illustrated in FIG. 9, the capacity Sh of the secondary battery 30 also suddenly decreases at the prescribed number of cycles Nt.

As a result, the estimation unit 56 estimates the degree of deterioration of the secondary battery 30 based on a location where the inclination of “Zb” suddenly increases. Specifically, for example, the information based on the impedance after 10 seconds Zb in the table described above includes one or more from among “Zb”, the inclination of “Zb”, and the rate of increase of the inclination of “Zb”. The estimation unit 56 estimates the degree of deterioration of the secondary battery 30 from the above-described multiple sources of information that includes the information based on the impedance after 10 seconds Zb, and the table described above. Whether or not the secondary battery 30 has deteriorated up to or greater than a prescribed reference is determined from the degree of deterioration.

By virtue of the present embodiment, as illustrated in FIG. 11, the estimation unit 56 comprehensively estimates the degree of deterioration of the secondary battery 30 from the impedance after 0.1 seconds Za and the impedance after 10 seconds Zb. Accordingly, it is possible to more accurately estimate the degree of deterioration.

### Other Embodiments

The embodiments described above can be modified as follows, for example. It may be that the electrolyte 35 in the secondary battery 30 illustrated in FIG. 2 is not a semi-solid electrolyte, but is a liquid electrolyte or an all-solid-state electrolyte. In other words, the secondary battery 30 may be a so-called liquid LiB, or an all-solid-state battery.

The prescribed timing described above may be other than the timing after 0.1 seconds. However, even in this case, the prescribed timing is desirably a timing at which a prescribed amount of time that is greater than or equal to 0.001 seconds and less than or equal to 1.0 seconds has elapsed from the start of discharging by the secondary battery 30. This is because, although it is possible to effectively exclude effects such as diffusion resistance if the amount of discharge time is short, when the amount of discharge time is too short, there is a greater chance of being affected by the inductance of a harness or the like, and accurate measurement is not possible. On this point, if the prescribed timing, which corresponds to a timing for measuring the internal impedance Z of the secondary battery 30, is before 1.0 seconds from the start of discharge elapses, the amount of discharge time is sufficiently short and thus it is possible to more effectively exclude the effect of diffusion resistance or the like. In addition, if this timing is a timing after 0.001 seconds or more has elapsed from the start of discharging by the secondary battery 30, the amount of discharge time will not be too short and there is a lower chance of being affected by the inductance of a harness or the like.

To be able to more reliably perform measurement before a steady state is reached, the prescribed timing is more desirably a timing at which a prescribed amount of time that is 0.5 seconds or less from the start of discharge has elapsed, and yet more desirably a timing at which a prescribed amount of time that is 0.2 seconds or less from the start of discharge has elapsed.

In the second embodiment, the above-described second prescribed timing may be a timing other than the timing after 10 seconds. However, even in this case, the second prescribed timing is desirably a timing at which a prescribed amount of time that is greater than or equal to 3 seconds and less than or equal to 30 seconds has elapsed from the start of discharging by the secondary battery 30. This is because, if the second prescribed timing is a timing at which 3 or more seconds have elapsed from the start of discharge, it is possible to sufficiently ensure an amount of time for the internal impedance Z of the secondary battery 30 to become steady. In addition, if the second prescribed timing is before 30 seconds from the start of discharge has elapsed, it is possible to avoid wastefully taking a large amount of time to obtain the internal impedance Z.

### EXPLANATION OF REFERENCE NUMERALS

30: Secondary battery
32: Negative electrode
32b: Negative electrode active material layer (metallic lithium layer)
35: Electrolyte
38: Positive electrode
50: Battery deterioration estimation apparatus
53: Voltage measurement unit
53b: (Second voltage measurement unit)
54: Current measurement unit
54b (Second current measurement unit)
55: Calculation unit
55b: Second calculation unit
56: Estimation unit
59: Reporting apparatus
100: Vehicle
Ia: Current after 0.1 seconds (discharge current of secondary battery at prescribed timing)
Ib: Current after 10 seconds (second discharge current)
V: Inter-terminal voltage of secondary battery (voltage of secondary battery)
ΔVa: Voltage drop after 0.1 seconds (Voltage drop by secondary battery at prescribed timing)
ΔVb: Voltage drop after 10 seconds (second voltage drop)
Z: Internal impedance
Za: Impedance after 0.1 seconds (internal impedance at prescribed timing)
Zb: Impedance after 10 seconds (internal impedance at second prescribed timing)

What is claimed is:

1. A battery deterioration estimation apparatus for estimating a degree of deterioration of a secondary battery that includes a positive electrode, a negative electrode, and an electrolyte provided between the positive electrode and the negative electrode, the negative electrode having a metallic lithium layer, the battery deterioration estimation apparatus comprising:
a current measurer configured to measure a discharge current of the secondary battery at a prescribed timing directly after a start of discharging by the secondary battery;
a voltage measurer configured to measure a voltage drop that is a difference between a voltage of the secondary battery before the start of discharging and a voltage of the secondary battery at the prescribed timing;
a calculator configured to calculate an internal impedance of the secondary battery at the prescribed timing from the measured discharge current and the measured voltage drop; and
an estimator configured to estimate the degree of deterioration of the secondary battery from the calculated internal impedance.

2. The battery deterioration estimation apparatus according to claim 1, wherein
the prescribed timing is a timing at which a prescribed amount of time that is greater than or equal to 0.001 seconds and less than or equal to 1.0 seconds has elapsed from the start of discharging by the secondary battery.

3. The battery deterioration estimation apparatus according to claim 1, further comprising:
a second current measurer configured to measure a second discharge current that is a discharge current of the secondary battery at a second prescribed timing that is after the prescribed timing;
a second voltage measurer configured to measure a second voltage drop that is a difference between the voltage of the secondary battery before the start of discharging and a voltage of the secondary battery at the second prescribed timing;
a second calculator configured to calculate an internal impedance of the secondary battery at the second prescribed timing from the measured second discharge current and the measured second voltage drop,
wherein the estimator comprehensively estimates the degree of deterioration of the secondary battery from the calculated internal impedance at the prescribed timing, and the calculated internal impedance at the second prescribed timing.

4. The battery deterioration estimation apparatus according to claim 3, wherein
the second prescribed timing is a timing at which a prescribed amount of time that is greater than or equal to 3.0 seconds and less than or equal to 30 seconds has elapsed from the start of discharging by the secondary battery.

5. The battery deterioration estimation apparatus according to claim 1, wherein
the secondary battery and the battery deterioration estimation apparatus are mounted to a vehicle.

6. The battery deterioration estimation apparatus according to claim 5, further comprising
a reporter configured to, on a condition that the estimator has determined that the secondary battery has deteriorated up to or greater than a prescribed reference, report to a driver of the vehicle that the secondary battery has deteriorated.

7. A battery deterioration estimation method for estimating a degree of deterioration of a secondary battery that includes a positive electrode, a negative electrode, and an electrolyte provided between the positive electrode and the negative electrode, the negative electrode having a metallic lithium layer, the battery deterioration estimation method comprising:
measuring a discharge current of the secondary battery at a prescribed timing directly after a start of discharging by the secondary battery;
measuring a voltage drop that is a difference between a voltage of the secondary battery before the start of discharging and a voltage of the secondary battery at the prescribed timing;
calculating an internal impedance of the secondary battery at the prescribed timing from the measured discharge current and the measured voltage drop; and
estimating the degree of deterioration of the secondary battery from the calculated internal impedance.
